(19) United States
(12) Patent Application Publication
(10) Pub. No.: US 2012/0193778 A1
(43) Pub. Date: Aug. 2, 2012

(54) INTEGRATED CIRCUIT HAVING PROTRUDING BONDING FEATURES WITH REINFORCING DIELECTRIC SUPPORTS

(75) Inventor: Kazuaki Mawatari, Beppu-City (JP)

(73) Assignee: TEXAS INSTRUMENTS INCORPORATED, Dallas, TX (US)

(21) Appl. No.: 13/015,140

(22) Filed: Jan. 27, 2011

(51) Int. Cl. H01L 23/48; H01L 21/56

(52) U.S. Cl. 257/737; 438/124; 257/E23.01; 257/E21.502

(57) ABSTRACT

An integrated circuit (IC) die includes a substrate including a topside surface having active circuitry and a bottomside surface. A plurality of protruding bonding features are on the topside surface or bottomside surface and include at least one metal. The protruding bonding features including sidewalls having a neck region that includes an interface at or proximate to the topside surface or the bottomside surface. The protruding bonding features extend outward to a distal top edge. A dielectric support is positioned on the topside surface or bottomside surface between protruding bonding features. The dielectric support contacts and surrounds the sidewalls of the neck regions, does not extend beyond a height of the distal top edge, and is at least twenty percent taller where contacting the sidewalls as compared to a minimum non-zero height in a location between adjacent bonding features.

### FIELD

Disclosed embodiments relate to integrated circuits (ICs) that include protruding bonding features.

### BACKGROUND

Traditionally, high temperature C4 (Controlled Collapse Chip Connection) bumps have been used to flip chip bond an IC die to a substrate. Conventionally, the C4 bumps are made from leaded solder. Pillars, typically copper pillars, have begun replacing solder bumps for flip chip bonding.

A typical copper pillar is 50 to 80 microns tall with a diameter from 25 to 60 microns having solder (e.g., PbSn) caps thereon that are coupled to and extend out from bond pads on the topside (active side) of the IC. A contact pad such as an under bump metallization (UBM) pad is conventionally between the pillar and the bond pad.

Copper pillar structures for ICs provide advantages for some packaging applications as compared to other flip chip attachment processes, for example as compared to conventional PbSn solder bumps. Advantages of copper pillars include copper having about one-fourth the electrical resistance of PbSn solder bumps and copper having higher current density capability thus being more electromigration resistant compared to PbSn bumps. Moreover, the thermal conductivity of copper is >3 times the thermal conductivity of solder, and copper pillars do not collapse during assembly, allowing for finer pitch without compromising stand-off height.

However, copper has a high Young's modulus and a high thermal expansion coefficient, such as compared to silicon. Thus, copper is not an ideal candidate for mitigating the coefficient of thermal expansion (CTE) mismatch between the IC (e.g., silicon) and conventional package substrates (e.g., organic laminate). Accordingly, stresses imposed during assembly cooling cycles cannot be effectively mitigated by the copper pillars, thus resulting in fractures, delaminations or other damage to the packaged device. For example, the copper pillar structure can crack at the point where the copper pillar meets the contact pad on the IC die.

Some ICs include through substrate vias (TSVs), commonly called through silicon vias, which can include protruding TSV tips that may provide another type of protruding bonding feature. In one arrangement, the TSV tips protrude from the bottomside of the IC die. The TSV tips are generally framed in a dielectric sleeve, except for their distal end that is bonded to. The dielectric sleeve at the base of the TSV where it emerges from the semiconductor surface can be cracked due to TSV deformation, such as during high pressure thermal compression (TC) bonding.

### SUMMARY

Disclosed embodiments describe integrated circuits (ICs) having protruding bonding features with reinforcing supports that help distribute lateral stress (the bend moment) that is applied to the base of protruding bonding features of the IC during IC assembly. In the case of pillars, the reinforcing supports can help reduce cracking at the base/neck of the pillar due to the coefficient of thermal expansion (CTE) mismatch between the semiconductor (e.g., silicon) substrate of the IC die and the package substrate (e.g., organic substrates) that can otherwise provide stress sufficient to exceed the bond strength between the pillar and the contact pad on the bond pad of the IC die to cause cracking at the base/neck of the pillar. In the case of protruding TSV tips, the reinforcing supports can help reduce cracking of the dielectric sleeve at the base of the TSV tip that can crack under stress conditions such as during high pressure thermal compression (TC) bonding.

One disclosed embodiment comprises IC die comprising a substrate including a topside surface having active circuitry and a bottomside surface, wherein the topside surface includes a plurality of bond pads. A plurality of protruding bonding features are on at least one of the topside surface (e.g., pillars) and bottomside surface (e.g., TSV tips) that comprise at least one metal. The protruding bonding features including sidewalls comprising a neck region that includes an interface at or proximate to at least one of the topside surface and the bottomside surface, and extend outward to a distal top edge. A dielectric support is positioned on the topside surface or bottomside surface between adjacent ones of the protruding bonding features. The dielectric supports contact and surround (360 degree coverage) the sidewalls of the neck regions of the protruding bonding feature, do not extend beyond a height of the distal top edge, and are at least twenty percent taller (and up to 3× taller, or more) where contact as made to the sidewalls as compared to a minimum non-zero height between adjacent protruding bonding features.

Another embodiment comprises a method of assembling an IC device and IC devices therefrom comprising providing a disclosed IC die having reinforcing dielectric supports between adjacent protruding bonding features, applying (e.g., coating) a resin layer (e.g., and epoxy resin) on the topside surface or bottomside surface between the protruding bonding features. The resin layer contacts and surrounds the sidewalls of the neck regions, does not extend beyond a height of the distal top edge, and is at least twenty percent taller where contacting the sidewalls as compared to a minimum non-zero height between protruding bonding features. The resin layer is at least partially cured, and the IC is then bonded to a workpiece, such as a ceramic or organic substrate. The at least partially cured resin layer provides reinforcing support to the neck region of the protruding bonding features during bonding that helps distribute lateral stress (the bend moment) that is applied to the base of protruding bonding features of the IC during IC assembly for reducing cracking at the base/neck of the protruding bonding feature.

The generally concave shape of the dielectric supports also provides for better for underfilling for capillary underflow by not blocking underfill flow to the extent of blocking by a planar layer. Moreover, the generally concave shape can reduce concern of die warpage due to resin cure shrinkage by reducing the material volume (again as compared to a planar layer). In addition, when the pillars, TSV tips or other protruding bonding features receive solder caps, the dielectric supports can control solder wetting to the sidewall of the protruding bonding features.

### BRIEF DESCRIPTION OF THE DRAWINGS

FIG. 1 is a cross sectional depiction of an IC die having reinforcing dielectric supports between adjacent pillars that protrude from the topside surface of the IC die, according to an example embodiment.

FIG. 2 is a cross sectional depiction of an IC die having reinforcing dielectric supports between adjacent TSV tips that protrude from the bottomside surface of the IC die, according to an example embodiment.

FIG. 3 is a cross sectional depiction of a stacked die assembly including a TSV die having reinforcing dielectric supports between adjacent TSV tips bonded to a substrate, and a top IC die on the TSV die, according to an example embodiment.

FIG. 4 is a flow chart for a method of assembling an IC device including an IC die having protruding bonding features with reinforcing dielectric supports between the protruding bonding, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

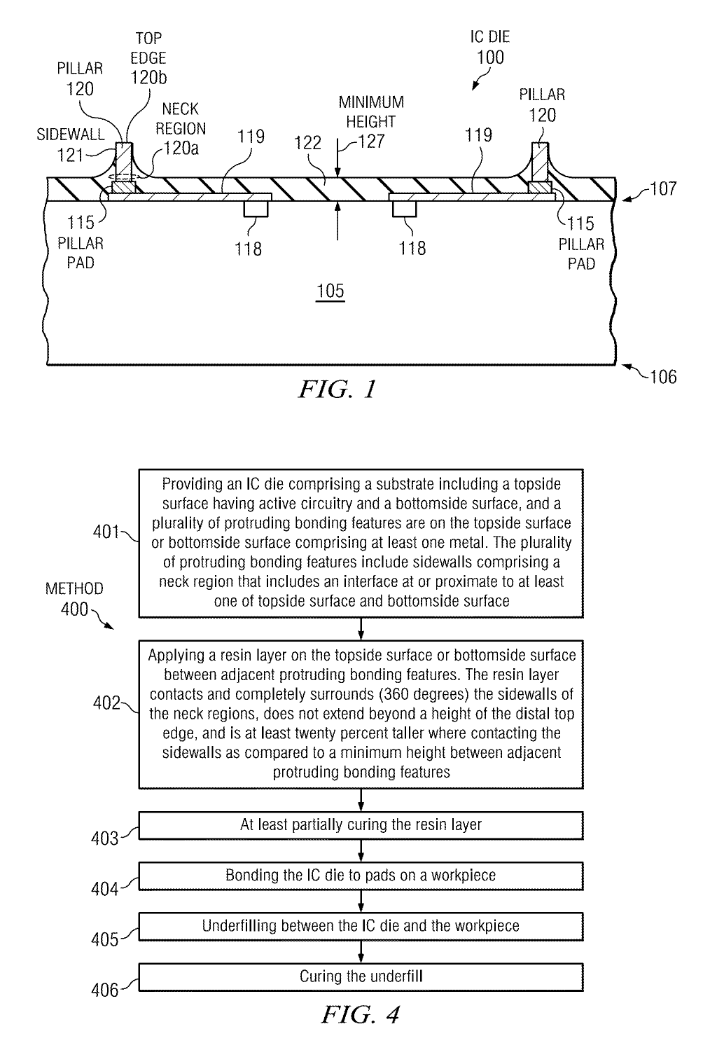

FIG. 1 is a cross sectional depiction of an IC die 100 having dielectric supports between adjacent pillars 120 that protrude from the topside surface of the IC die, according to an example embodiment. IC die 100 comprises a substrate 105 having a topside semiconductor surface 107 having active circuitry 118 configured to provide an IC circuit function (e.g., a memory of logic die), and a bottomside surface 106. The active circuitry 118 is shown coupled to bond pads 115 shown as pillar pads 115, such as by a metal interconnect layer 119 (e.g., M1, or M2, etc.). The pillars 120 comprise at least one metal, are on pillar pads 115, and are thus proximate to the topside semiconductor surface 107. Pillars 120 are generally at least 25 μm tall. Pillars 120 can comprise copper or other low resistance metal or metal alloy. Dielectric layer 122 is shown on the topside semiconductor surface 107.

Pillars 120 include sidewalls 121 comprising a neck region 120(a) that includes an interface with pillar pads 115. Pillars 120 extend outward from the topside semiconductor surface 107 to a distal top edge 120(b). Dielectric layer 122 is between adjacent pillars 120 shown in FIG. 1 as being suspension shaped. In the region between pillars 120, dielectric layer 122 provides a dielectric support “bridge” between adjacent pillars 120. The dielectric supports contact and surround (360 degrees) the sidewalls 121 of the neck regions 120(a) of pillars 120, do not extend beyond a height of the distal top edge 120(b), and are at least twenty percent taller where contacting the sidewalls 121 as compared to a minimum non-zero height between adjacent pillars 120, such as in the location marked “minimum height” 127 that is roughly midway between the pillars 120 shown in FIG. 1. For example, for 60 μm tall pillars 120, the height of the dielectric layer 122 along sidewalls can be 15 to 50 μm, while the minimum height for dielectric layer 122 between adjacent pillars 120 can be 2 to 10 μm.

Having dielectric layer 122 extend the full length of the distance between pillars or other protruding bonding features provides additional structural support as compared to an arrangement where the dielectric layer does not extend the full length of the distance between pillars or other protruding bonding features. The dielectric layer 122 can comprise a thermoset or thermoplastic material. In one embodiment the thermoset or thermoplastic material can be formed by curing an epoxy material. In one embodiment dielectric layer 122 comprises a B-stage resin. As known in the polymer arts, a B-stage resin is not fully polymerized, such as a middle stage of the reaction of a thermosetting resin. B-stage resins are generally capable of being softened by heating and expand, but are generally insoluble in solvents.

The concave shape of the dielectric supports (shown as suspension shaped) provided by dielectric layer 122 provides for better underfilling for capillary underflow by not blocking underfill flow to the extent a planar layer would block capillary underfilling. Moreover, the concave shape can reduce die warpage due to resin cure shrinkage by reducing the material volume again as compared to a planar layer. In addition, when the pillars 120 or other bonding features receive solder caps, the support provided by dielectric layer 122 can control solder wetting to the sidewall 121 of the pillars 120 or other bonding features.

Substrate 105 can include a variety of semiconductors such as GaAs, Group III-N semiconductors (e.g., GaN), and silicon, including certain compounds (alloys) of silicon, including but not limited to, silicon germanium (SiGe) and silicon carbide (SiC). Semiconductor on insulator (SOI), such as silicon on insulator, can also be used.

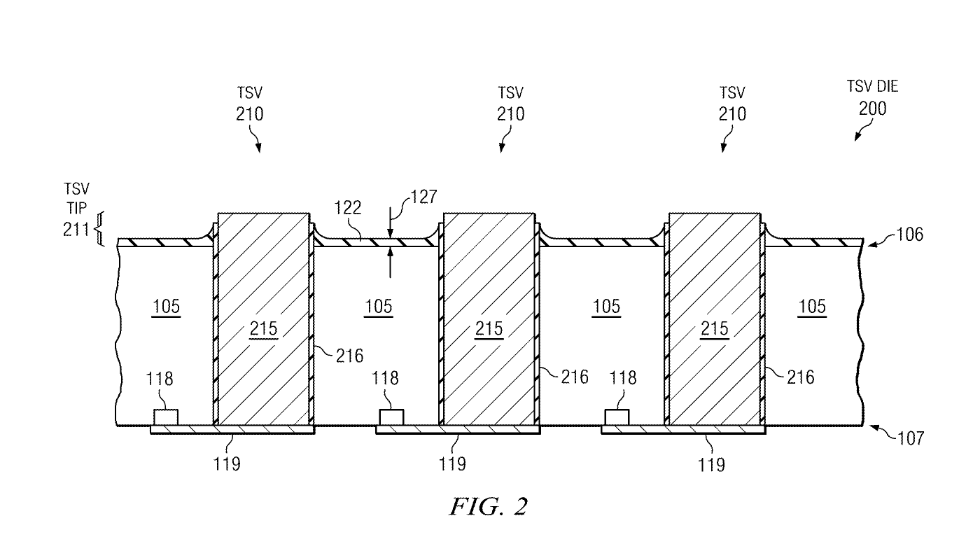

FIG. 2 is a cross sectional depiction of an IC die 200 referred to as a TSV die 200 having dielectric supports between adjacent TSV tips 211 that protrude from the bottomside surface of the IC die 200, according to an example embodiment. In one embodiment a length of the protruding TSV tips 211 measured from the bottomside surface 106 is from 5 to 15 μm. Dielectric supports are provided by the dielectric layer 122 between TSV tips 211. TSVs 210 includes electrically conductive inner core portion 215 and an outer dielectric sleeve/liner 216 (e.g., SiO₂, PSG, or SiN, or combinations thereof). The active circuitry 118 is shown coupled to TSVs 210 on the topside semiconductor surface 107 by metal interconnect layer 119 (e.g., M1, or M2, etc.). Although not shown, in the case of copper and certain other metals for the inner metal core 215, a metal diffusion barrier layer referred to as a “TSV barrier” is generally added between the inner metal core 215 and outer dielectric sleeve 216, such as a refractory metal or a refractory metal nitride. For example, TSV barrier materials can include materials including Ta, W, Mo, Ti, TiW, TiN, TaN, WN, TiSiN or TaSiN, which can be deposited by physical vapor deposition (PVD) or chemical vapor deposition (CVD). The TSV barrier is typically 100-500 Å thick.

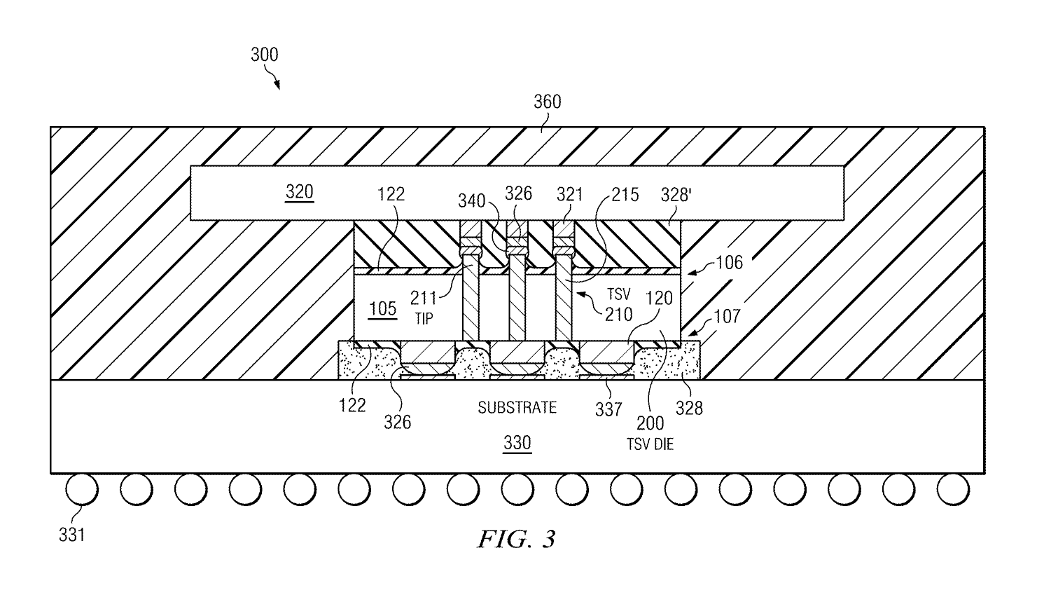

FIG. 3 is a cross sectional depiction of a stacked die assembly 300 comprising a top IC die (or die stack) 320 on a TSV die 200 on a substrate 330, including reinforcing dielectric supports, according to an example embodiment. Dielectric layer 122 is both between pillars 120 on the topside semiconductor surface 107 and TSV tips 211 having TSV caps 340 thereon and bottomside surface 106 of TSV die 200. Top die 320 that includes pads 321 that are bonded by solder 326 to TSV tips 211 on the bottomside 106 of TSV die 200. Workpiece 330 shown as a package substrate includes pads 337 that are bonded to pillars 120 via solder 326.

Solder 326 can be introduced from top die 320, and can be a different solder composition compared to the solder 326 between the TSV caps 340 and pads 321. Underfill between TSV die 200 and workpiece 330 is shown as 328, while underfill between TSV die 200 and top die 320 is shown as 328′ indicating the possibility for different underfill compositions. The package substrate 330 is shown including a BGA comprising a plurality of solder balls 331.

TSV caps 340 can be formed by depositing a first metal layer on the distal end of the TSV tips. For example, a first metal layer exclusive of solder can be electrolessly or electrolytically deposited (i.e., electroplating) on the distal end of the protruding TSV tips 211. The first metal layer forms an electrical contact with at least the topmost surface of the inner metal core of the TSV tip. The first metal layer is generally 1 to 4 μm thick. The first metal layer can provide both an IMC block and current spreader function for the TSV tip. The first metal layer can comprise materials including Ni, Pd, Co, Cr, Rh, NiP, NiB, CoWP or CoP, for example.

FIG. 4 is a flow chart for a method 400 of assembling an IC device including an IC die having protruding bonding features with reinforcing supports between the protruding bonding features that help distribute lateral stress (the bend moment) applied to the base of protruding bonding features of the IC during IC assembly, according to an example embodiment. Step 401 comprises providing an IC die comprising a substrate including a topside surface having active circuitry and a bottomside surface, wherein the topside surface includes a plurality of bond pads, where a plurality of protruding bonding features are on the topside surface or bottomside surface comprising at least one metal. The plurality of protruding bonding features include sidewalls comprising a neck region that includes an interface at or proximate to at least one of topside surface and bottomside surface. The plurality of protruding bonding features extend outward to a distal top edge. Step 402 comprises applying a resin layer on the topside surface or bottomside surface between adjacent protruding bonding features. The resin can be a thermosetting or thermoplastic resin. The resin layer contacts and completely surrounds (360 degrees) the sidewalls of the neck regions, does not extend beyond a height of the distal top edge, and is at least twenty percent taller where contacting the sidewalls as compared to a minimum non-zero height between adjacent protruding bonding features.

Step 403 comprises at least partially curing the resin layer. In one embodiment, the resin is only partially cured to provide a B-stage resin. Use of a B-stage resin can be reduce the curing time in step 403. In another embodiment, the resin is fully cured by step 403.

In one embodiment the resin provides both low viscosity and low surface tension. For example, the viscosity can be in a range of 100 centipoise and about 20,000 centipoise at 25° C., such as between 500 centipoise (5 Pa·s) and 2000 centipoise (20 Pa·s) at 25° C. The surface tension of the resin can be in a range between 10 to 70 mN/m at 25° C., such as between 20 mN/m and 35 mN/m at 25° C. Low surface tension provides enhanced surface wetting, and better adhesion.

Step 404 comprises bonding the IC die to pads on a workpiece. The workpiece can comprise, for example, a leadframe, an organic substrate, a ceramic substrate, a silicon substrate, or a silicon interposer. Step 405 comprises underfilling between the IC and the workpiece. The underfilling can comprise capillary underfilling. Step 406 comprises underfill curing. In the case of a B-stage resin at step 403, following underfill curing the resin will generally become fully cured.

The active circuitry formed on the semiconductor substrate comprises circuit elements that may generally include transistors, diodes, capacitors, and resistors, as well as signal lines and other electrical conductors that interconnect the various circuit elements to provide an IC circuit function. As used herein “provide an IC circuit function” refers to circuit functions from ICs, that for example may include an application specific integrated circuit (ASIC), a digital signal processor, a radio frequency chip, a memory, a microcontroller and a system-on-a-chip or a combination thereof. Disclosed embodiments can be integrated into a variety of process flows to form a variety of devices and related products. The semiconductor substrates may include various elements therein and/or layers thereon. These can include barrier layers, other dielectric layers, device structures, active elements and passive elements, including source regions, drain regions, bit lines, bases, emitters, collectors, conductive lines, conductive vias, etc. Moreover, disclosed embodiments can be used in a variety of semiconductor device fabrication processes including bipolar, CMOS, BiCMOS and MEMS processes.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

I claim:

1. An integrated circuit (IC) die, comprising:
a substrate including a topside surface having active circuitry and a bottomside surface, wherein said topside surface includes a plurality of bond pads;
a plurality of protruding bonding features on said topside surface or said bottomside surface comprising at least one metal, said plurality of protruding bonding features including sidewalls comprising a neck region that includes an interface at or proximate to at least one of said topside surface and said bottomside surface, said plurality of protruding bonding features extending outward to a distal top edge, and
a dielectric support positioned on said topside surface or said bottomside surface between adjacent ones of said plurality of protruding bonding features, said dielectric support contacting and surrounding said sidewalls of said neck regions, not extending beyond a height of said distal top edge, and being at least twenty percent taller where contacting said sidewalls as compared to a minimum non-zero height between adjacent ones of said plurality of protruding bonding features.

2. The IC die of claim 1, wherein said plurality of protruding bonding features comprise copper pillars that are at least 25 μm tall that are coupled to said plurality of bond pads.

3. The IC die of claim 1, wherein said plurality of protruding bonding features comprise TSVs comprising an inner copper core and an outer dielectric sleeve that extend from said topside surface to protruding TSV tips that protrude at least 5 μm from said bottomside surface.

4. The IC die of claim 1, wherein said dielectric support comprises a B-stage resin.

5. The IC die of claim 1, wherein said dielectric support comprise a fully cured thermosetting resin.

6. The IC die of claim 1, wherein said dielectric support comprise a fully cured thermoplastic resin.

7. The IC die of claim 1, wherein said plurality of protruding bonding features comprise through substrate vias (TSVs) comprising an inner copper core and an outer dielectric sleeve that extend from said topside surface to protruding TSV tips that protrude at least 5 μm from said bottomside surface, and a plurality of copper pillars that are at least 25 μm tall that are coupled to said plurality of bond pads on said frontside surface.

8. An integrated circuit (IC) device, comprising:
a workpiece having a top surface and a bottom surface opposite to said top surface, wherein said top surface includes a plurality of workpiece bonding pads;
an IC die, comprising:
a substrate including a topside surface having active circuitry and a bottomside surface, wherein said topside surface includes a plurality of bond pads;
a plurality of protruding bonding features on said topside surface or said bottomside surface comprising at least one metal, said plurality of protruding bonding features including sidewalls comprising a neck region that includes an interface at or proximate to at least one of said topside surface and said bottomside surface, said plurality of protruding bonding features extending outward to a distal top edge, and
a dielectric support positioned on said topside surface or said bottomside surface between adjacent ones of said plurality of protruding bonding features, said dielectric support contacting and surrounding said sidewalls of said neck regions, not extending beyond a height of said distal top edge, and being at least twenty percent taller where contacting said sidewalls as compared to a minimum non-zero height between adjacent ones of said plurality of protruding bonding features,
wherein said plurality of protruding bonding features are bonded to said plurality of workpiece bonding pads.

9. The IC device of claim 8, wherein said plurality of protruding bonding features comprise copper pillars that are at least 25 μm tall and are coupled to said plurality of bond pads.

10. The IC device of claim 8, wherein said plurality of protruding bonding features comprise through substrate vias (TSVs) comprising an inner copper core and an outer dielectric sleeve that extend from said topside surface to protruding TSV tips that protrude at least 5 μm from said bottomside surface.

11. The IC device of claim 8, further comprising underfill lateral to joints between said plurality of protruding bonding features and said plurality of workpiece bonding pads, wherein a composition for said underfill is different from a composition for said dielectric supports.

12. The IC device of claim 8, wherein said IC die comprises a through substrate via (TSV) die, and wherein said plurality of protruding bonding features comprise TSVs comprising an inner copper core and an outer dielectric sleeve that extend from said topside surface to protruding TSV tips that protrude at least 5 μm from said bottomside surface, and a plurality of copper pillars that are at least 25 μm tall that are coupled to said plurality of bond pads on said frontside surface,
further comprising a top IC die bonded to said copper pillars of said TSV die.

13. A method of assembling an integrated circuit (IC) device, comprising:
providing an IC die comprising a substrate including a topside surface having active circuitry and a bottomside surface, wherein said topside surface includes a plurality of bond pads, a plurality of protruding bonding features on said topside surface or said bottomside surface comprising at least one metal, said plurality of protruding bonding features including sidewalls comprising a neck region that includes an interface at or proximate to at least one of said topside surface and said bottomside surface, said plurality of protruding bonding features extending outward to a distal top edge;
applying a resin layer on said topside surface or said bottomside surface between adjacent ones of said plurality of protruding bonding features, said resin layer contacting and surrounding said sidewalls of said neck regions, not extending beyond a height of said distal top edge, and being at least twenty percent taller where contacting said sidewalls as compared to a minimum non-zero height between adjacent ones of said plurality of protruding bonding features,
at least partially curing said resin layer, and
bonding said IC die to workpiece bonding pads on a workpiece.

14. The method of claim 13, wherein said at least partially curing said resin layer provides a B-stage resin.

15. The method of claim 13, wherein said at least partially curing said resin layer comprises fully curing said resin to provide a fully cured resin.

16. The method of claim 13, wherein said applying said resin layer comprises:
applying a resin material to fill an entire volume between adjacent ones of said plurality of protruding bonding features and to place said resin material on said distal top edge of said plurality of protruding bonding features, and
pressing using a mold press having protrusions sized and aligned to fit between adjacent ones of said plurality of protruding bonding features to selectively remove said resin from said distal top edge of said plurality of protruding bonding features and to provide said twenty percent taller.

17. The method of claim 13, wherein said applying said resin layer comprises:
spin coating to provide a resin material between adjacent ones and on said distal top edge of said plurality of protruding bonding features, and
backgrinding to selectively remove said resin material from said distal top edge of said plurality of protruding bonding features.

18. The method of claim 13, wherein said workpiece comprises an organic substrate.

19. The method of claim 13, further comprising capillary underfilling with an underfill composition between said IC die and said workpiece after said bonding, wherein said underfill composition is different from a composition of said resin layer.

20. The method of claim 13, wherein said resin layer before said partially curing provides a viscosity in a range between 100 centipoise and 20,000 centipoise at 25° C., and a surface tension in a range between 500 to 10,000 mPa·s at 25° C.
